(19) United States
(12) Patent Application Publication
(10) Pub. No.: US 2025/0369087 A1
(43) Pub. Date: Dec. 4, 2025

(54) SHUTTER APPARATUS FOR USE IN A PART-MANUFACTURING PROCESS AND ASSOCIATED SYSTEM AND METHOD

(71) Applicant: The Boeing Company, Arlington, VA (US)

(72) Inventors: James M. Kestner, Seattle, WA (US); Daniel Perron, Federal Way, WA (US); Darrick Hay, Kent, WA (US); Derrick Ong, Shoreline, WA (US)

(21) Appl. No.: 18/678,541

(22) Filed: May 30, 2024

(51) Int. Cl. C23C 14/04; C23C 14/50

(52) U.S. Cl. CPC C23C 14/042; C23C 14/505

(57) ABSTRACT

A shutter apparatus for use in a part-manufacturing process is disclosed. The shutter apparatus includes a platen having a plurality of substrate locations. The shutter apparatus also includes a shutter defining a substrate-location aperture. The shutter covers the platen except for a selectable one of the plurality of substrate locations of the platen exposed through the substrate-location aperture. The substrate-location aperture is sized to expose only one of the plurality of substrate locations at a time, such that the shutter covers all but a selected one of the plurality of substrate locations. The shutter and the platen are selectively rotatable, relative to each other, to alternatingly expose a different selected one of the plurality of substrate locations.

### FIELD

This disclosure relates generally to a shutter apparatus, and more particularly to a shutter apparatus for use in a part-manufacturing process.

### BACKGROUND

In vacuum coating systems, optimizing coating performance often requires conducting multiple coating runs to evaluate various process parameters, where each coating run tests a single process parameter. Traditionally, vacuum coating systems require cycling from atmospheric pressure to vacuum and back to atmospheric pressure for each coating run. This cyclic process can be time-consuming, particularly in large-format systems, where each coating run may span a full day or more to complete.

Certain coating processes, such as sputtering, demand extensive test matrices to comprehensively evaluate process parameters, which can necessitate numerous coating runs. Conducting numerous coating runs to evaluate these parameters is a laborious and time-intensive process, which can result in a test phase that can last weeks, months or even years to complete. This prolonged testing phase hinders efficient process development and optimization of vacuum coating systems.

### SUMMARY

The subject matter of the present application has been developed in response to the present state of the art, and in particular, in response to the problems of and needs created by, or not yet fully solved by, existing vacuum coating systems. Generally, the subject matter of the present application has been developed to provide a shutter apparatus for a vacuum coating system, and associated systems and methods, that overcome at least some of the above-discussed shortcomings of the prior art techniques.

Disclosed herein is a shutter apparatus for use in a part-manufacturing process. The shutter apparatus includes a platen having a plurality of substrate locations. The shutter apparatus also includes a shutter defining a substrate-location aperture and covering the platen except for a selectable one of the plurality of substrate locations of the platen exposed through the substrate-location aperture. The substrate-location aperture is sized to expose only one of the plurality of substrate locations at a time, such that the shutter covers all but a selected one of the plurality of substrate locations. The shutter and the platen are selectively rotatable, relative to each other, to alternatingly expose a different selected one of the plurality of substrate locations. The preceding subject matter of this paragraph characterizes example 1 of the present disclosure.

The platen is rotatable, in a rotational direction, relative to the shutter, which is rotationally fixed. The preceding subject matter of this paragraph characterizes example 2 of the present disclosure, wherein example 2 also includes the subject matter according to example 1, above.

Alternatively, the shutter is rotatable, in a rotational direction, relative to the platen, which is rotationally fixed. The preceding subject matter of this paragraph characterizes example 3 of the present disclosure, wherein example 3 also includes the subject matter according to example 1, above.

The platen has a circular base. The plurality of substrate locations are spaced apart about and adjacent to a circumference of the circular base. Each one of the plurality of substrate locations is located equidistant from corresponding adjacent ones of the plurality of substrate locations. The preceding subject matter of this paragraph characterizes example 4 of the present disclosure, wherein example 4 also includes the subject matter according to any of examples 1-3, above.

The plurality of substrate locations are arranged in a circular pattern. Each one of the plurality of substrate locations are spaced apart from others of the plurality of substrate locations an equal distance away from corresponding adjacent ones of the plurality of substrate locations. Each one of the plurality of substrate locations are spaced an equal distance away from a center of the circular pattern. The preceding subject matter of this paragraph characterizes example 5 of the present disclosure, wherein example 5 also includes the subject matter according to any of examples 1-4, above.

The plurality of substrate locations includes between, and inclusive of, two and twelve substrate locations. The preceding subject matter of this paragraph characterizes example 6 of the present disclosure, wherein example 6 also includes the subject matter according to any of examples 1-5, above.

The plurality of substrate locations includes at least twelve substrate locations. The preceding subject matter of this paragraph characterizes example 7 of the present disclosure, wherein example 7 also includes the subject matter according to any of examples 1-6, above.

Each one of the plurality of substrate locations defines a recess within the platen that is configured to hold a corresponding substrate. The preceding subject matter of this paragraph characterizes example 8 of the present disclosure, wherein example 8 also includes the subject matter according to any of examples 1-7, above.

The shutter apparatus includes a pedestal having an outer stem and an inner stem, within the outer stem. The outer stem is coupled to the platen and the inner stem is coupled to the shutter. The preceding subject matter of this paragraph characterizes example 9 of the present disclosure, wherein example 9 also includes the subject matter according to any of examples 1-8, above.

Further disclosed herein is a vacuum coating system that includes a vacuum chamber having a deposition chamber. The vacuum coating system also includes a substrate carrier within the deposition chamber and having a rotatable portion, which is selectively rotatable relative to the deposition chamber, and a non-rotatable portion, which is non-rotatably fixed relative to the deposition chamber. The vacuum coating system further includes a shutter apparatus coupled to the substrate carrier. The shutter apparatus includes a platen having a plurality of substrate locations. The shutter apparatus also includes a shutter defining a substrate-location aperture and covering the platen except for a selectable one of the plurality of substrate locations of the platen exposed through the substrate-location aperture. The platen is positioned between the substrate carrier and the shutter. The substrate-location aperture is sized to expose only one of the plurality of substrate locations at a time, such that the shutter covers all but a selected one of the plurality of substrate locations. The platen is coupled to one of the rotatable portion or the non-rotatable portion of the substrate carrier and the shutter is coupled to the other one of the rotatable portion or the non-rotatable portion of the substrate carrier. The platen and the shutter are selectively rotatable, relative to each other, to alternatively expose a different selected one of the plurality of substrate locations. The preceding subject matter of this paragraph characterizes example 10 of the present disclosure.

The rotatable portion of the substrate carrier includes a rotating ring and the non-rotatable portion of the substrate carrier includes a fixed base. The platen is coupled to the rotating ring, such that the platen and the rotating ring are co-rotatable in a rotational direction, relative to the deposition chamber. The shutter is coupled to the fixed base, such that the shutter is rotationally fixed. The preceding subject matter of this paragraph characterizes example 11 of the present disclosure, wherein example 11 also includes the subject matter according to example 10, above.

The shutter is coupled to the rotatable portion, such that the shutter and the rotatable portion are co-rotatable in a rotational direction, relative to the deposition chamber. The platen is coupled to the non-rotatable portion such that the platen is rotationally fixed. The preceding subject matter of this paragraph characterizes example 12 of the present disclosure, wherein example 12 also includes the subject matter according to example 10, above.

The substrate carrier is translationally movable along the deposition chamber. The preceding subject matter of this paragraph characterizes example 13 of the present disclosure, wherein example 13 also includes the subject matter according to any of examples 10-12, above.

The vacuum coating system includes a plurality of substrates. Each one of the plurality of substrates is configured to be positioned within a corresponding one of the plurality of substrate locations of the platen. The preceding subject matter of this paragraph characterizes example 14 of the present disclosure, wherein example 14 also includes the subject matter according to any of examples 10-13, above.

The vacuum coating system includes a plurality of substrate trays. Each one of the plurality of substrate trays is configured to support at least one of the plurality of substrates. Each one of the plurality of substrate trays is configured to be positioned within a corresponding one of the plurality of substrate locations of the platen. The preceding subject matter of this paragraph characterizes example 15 of the present disclosure, wherein example 15 also includes the subject matter according to example 14, above.

Each one of the plurality of substrates is a test coupon. The preceding subject matter of this paragraph characterizes example 16 of the present disclosure, wherein example 16 also includes the subject matter according to example 14, above.

Each one of the plurality of substrates is a production part. The preceding subject matter of this paragraph characterizes example 17 of the present disclosure, wherein example 17 also includes the subject matter according to example 14, above.

Further disclosed herein is a method of making parts within a vacuum coating system. The method includes rotating a platen or a shutter, relative to each other, to alternatingly expose a selected one of a plurality of substrate locations of the platen through a substrate-location aperture of the shutter. The method also includes alternatively depositing material through the substrate-location aperture of the shutter on the selected one of the plurality of substrate locations only when the selected one of the plurality of substrate locations is exposed through the substrate-location aperture. The preceding subject matter of this paragraph characterizes example 18 of the present disclosure.

The platen is coupled to one of a rotatable portion or a non-rotatable portion of a substrate carrier and the shutter is coupled to the other one of the rotatable portion or the non-rotatable portion of the substrate carrier. The step of rotating the platen or the shutter, relative to each other includes rotating the rotatable portion of the substrate carrier, relative to the non-rotatable portion of the substrate carrier. The preceding subject matter of this paragraph characterizes example 19 of the present disclosure, wherein example 19 also includes the subject matter according to example 18, above.

The step of alternatively depositing material through the substrate-location aperture of the shutter on the selected one of the plurality of substrate locations includes depositing material on at least another selected one of the plurality of substrate locations that is different from the material deposited on the selected one of the plurality of substrate locations. The preceding subject matter of this paragraph characterizes example 20 of the present disclosure, wherein example 20 also includes the subject matter according to any of examples 18-19, above.

The described features, structures, advantages, and/or characteristics of the subject matter of the present disclosure may be combined in any suitable manner in one or more examples, including embodiments and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example, embodiment, or implementation. In other instances, additional features and advantages may be recognized in certain examples, embodiments, and/or implementations that may not be present in all examples, embodiments, or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific examples that are illustrated in the appended drawings. Understanding that these drawings depict only typical examples of the subject matter, they are not therefore to be considered to be limiting of its scope. The subject matter will be described and explained with additional specificity and detail through the use of the drawings, in which:

FIG. 1 is a schematic perspective view of a shutter apparatus for use in a part-manufacturing process, according to one or more examples of the present disclosure;

FIG. 2A is a schematic cross-sectional view of a shutter apparatus, with a platen that is rotatable relative to a shutter, according to one or more examples of the present disclosure;

FIG. 2B is a schematic cross-sectional view of a shutter apparatus, with a shutter that is rotatable relative to a platen, according to one or more examples of the present disclosure;

FIG. 3 is a schematic perspective view of the shutter apparatus of FIG. 1, without a shutter, according to one or more examples of the present disclosure;

FIG. 4 is a schematic perspective view of a platen of the shutter apparatus of FIG. 1, according to one or more examples of the present disclosure;

FIG. 5 is a schematic perspective view of a substrate tray of a vacuum coating system, according to one or more examples of the present disclosure;

FIG. 6 is a schematic, front, perspective view of a vacuum coating system, according to one or more examples of the present disclosure;

FIG. 7 is a schematic, side, perspective view of the vacuum coating system of FIG. 6, with a side panel of the vacuum chamber removed, according to one or more examples of the present disclosure;

FIG. 8 is a schematic perspective view of a substrate carrier within a deposition chamber of a vacuum coating system, according to one or more examples of the present disclosure;

FIG. 9A is a schematic perspective view of a shutter apparatus coupled to a substrate carrier and rotating in a rotational direction, with a first substrate exposed by a substrate-location aperture, according to one or more examples of the present disclosure;

FIG. 9B is a schematic perspective view of the shutter apparatus coupled to the substrate carrier of FIG. 9A, with a subsequent substrate exposed by the substrate-location aperture; and

FIG. 10 is a schematic flow diagram of a method of making parts with a vacuum coating system, according to one or more examples of the present disclosure.

### DETAILED DESCRIPTION

Reference throughout this specification to “one example,” “an example,” or similar language means that a particular feature, structure, or characteristic described in connection with the example is included in at least one example of the subject matter of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the subject matter of the present disclosure, however, absent an express correlation to indicate otherwise, an implementation may be associated with one or more examples.

Disclosed herein are examples of a shutter apparatus and an associated system and method. The following provides some features of at least one example of the shutter apparatus and associated system and method. The shutter apparatus is designed to be utilized within a part-manufacturing process, such as a vacuum coating process within a vacuum coating system. It enables multiple individual substrates or multiple groups of substrates to be manufactured (i.e., coated) independently within a vacuum coating system during a single vacuum cycle. In some examples, the shutter apparatus is couplable to an existing substrate carrier within the vacuum coating system and utilizes the rotational capabilities of the substrate carrier to rotate part of the shutter apparatus to expose a select substrate or a select group of substrates. That is, either a platen or a shutter component of the shutter apparatus can be selectively rotated, relative to each other, via the substrate carrier. Accordingly, there is no requirement for additional power or control channels to directly manage the shutter apparatus. Therefore, the design simplifies both implementation and utilization of the shutter apparatus.

A vacuum coating system is often utilized for process development of a substrate design and often requires performing multiple coating runs to evaluate the effect of various process parameters, as each coating run is dedicated to testing a process parameter on an individual substrate or an individual group of substrates. Typically, each coating run requires cycling the vacuum coating system from atmospheric pressure to vacuum and back to atmospheric pressure for each coating run, making it a time-consuming process. The shutter apparatus enables independent processing of multiple substrates within a single coating run, streamlining the development process and reducing the need for repeating cycling of the vacuum coating system. That is, the total time required to complete the process development is reduced by the number of individual substrates or individual groups of substrates within the shutter apparatus. In other words, as the shutter apparatus is configured to cover all but a selectable individual substrate or selectable groups of substrates, only the selected substrate(s) are exposed to the coating process, eliminating the need for cycling the entire vacuum coating system multiple times for multiple substrates.

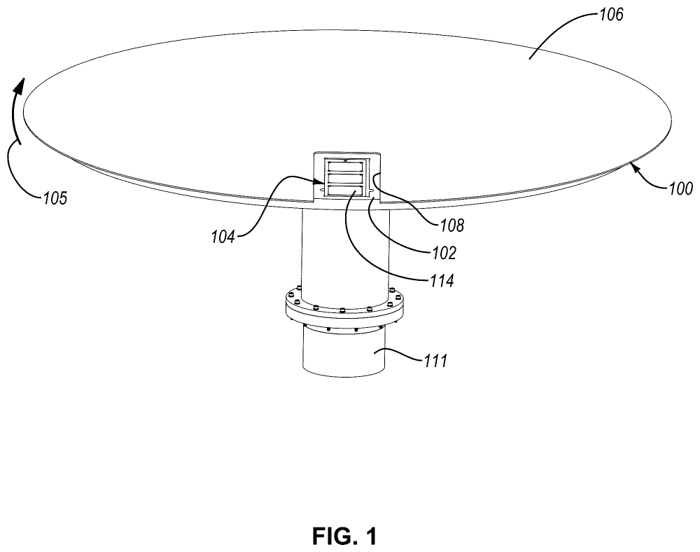

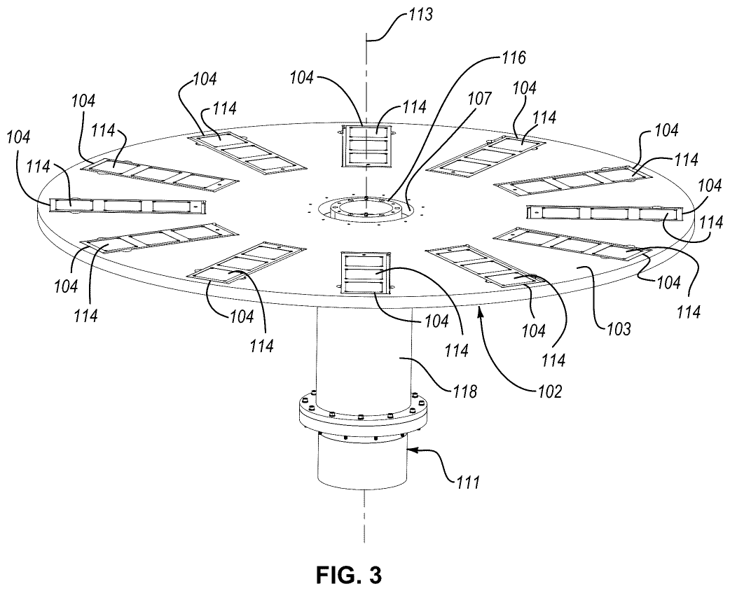

Referring to FIG. 1, one example of a shutter apparatus 100 is shown. The shutter apparatus 100 includes a platen 102 and a shutter 106. The platen 102 has a plurality of substrate locations 104 (see, i.e., FIG. 3). The shutter 106 is located proximate to the platen 102, and in some examples, is located vertically above the platen 102. Moreover, the shutter 106 covers the platen 102, except for a selected one of the plurality of substrate locations 104 of the platen 102. That is, the shutter 106 defines a substrate-location aperture 108 within which the selected one of plurality of substrate locations 104 of the platen 102 is exposed (i.e., not covered). In other words, the substrate-location aperture 108 is an opening within the shutter 106 that is sized and shaped to expose only one of the plurality of substrate locations 104 of the platen 102 at a time, such that the shutter 106 covers all but a selected one of the plurality of substrate locations 104. The substrate-location aperture 108 may have a shape that is circular, rectangular, curved, irregular, etc., and may be optimally shaped based on the shape and size of one of the plurality of substrate locations 104. In some examples, the substrate-location aperture 108 has a fully enclosed design, where the aperture is positioned entirely within a perimeter of the shutter 106. In other examples, the substrate-location aperture 108 has a partially open design, where the aperture extends inward from an edge of the shutter 106.

The shutter 106 and the platen 102 are selectively rotatable, relative to each other, to alternatingly expose a different selected one of the plurality of substrate locations 104. In other words, the shutter 106 or the platen 102 can be rotated, relative to each other, to expose different ones of the plurality of substrate locations 104, one at a time. In some examples, the platen 102 is rotatable, in a rotational direction 105, relative to the shutter 106, which is rotationally fixed, relative to a vacuum chamber. That is, the platen 102 is moved to expose different ones of the plurality of substrate locations 104 as the shutter remains stationary. In other examples, the shutter 106 is rotatable, in a rotational direction 105, relative to the shutter 106, which is rotationally fixed, relative to a vacuum chamber. That is, the shutter 106 is moved to expose different ones of the plurality of substrate locations 104 as the platen remains stationary. The rotational direction 105 may be unidirectional or bi-directional, allowing rotational movement in either a clockwise direction, a counterclockwise direction, or both.

The plurality of substate locations 104 are each configured to support a substrate 114 therein or thereon. As used herein, a substrate 114 is a solid material or surface upon which a coating, deposition, or other manufacturing process is applied. It serves as the foundation or base for the desired material or layer to be added during a part manufacturing process. The substrate 114 may vary in composition, size, and shape, depending on the specific application and requirements of the manufacturing process. Moreover, the substrate 114 may be used for during the part manufacturing process for numerous industries, including electronics and optics.

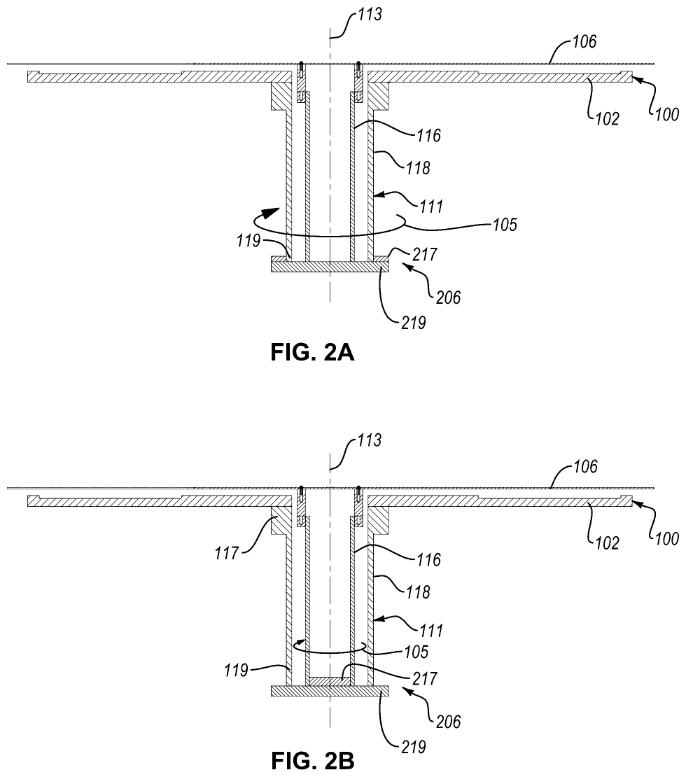

In some examples, the shutter apparatus 100 includes a pedestal 111. The pedestal 111 is attachable to the shutter apparatus 100 at a first end, and attachable to a substrate carrier at a second end (see, i.e., FIGS. 2A and 2B). In other words, the pedestal 111 is utilized to attach the shutter apparatus 100 to the substrate carrier. The pedestal 111 can be any of a various lengths, such that the shutter apparatus 100 can be attached at a distance from the substrate carrier. That is, the pedestal 111 is a support structure that elevates the shutter apparatus 100 above the substrate carrier. The pedestal 111 may be a cylindrically shaped column. In other examples, the shutter apparatus 100 may be attached to a substrate carrier without a pedestal, such as directly attaching the shutter apparatus 100 to the substrate carrier.

Referring to FIGS. 2A and 2B, the pedestal 111 includes an inner stem 116 and an outer stem 118, which is hollow. The inner stem 116 is within the outer stem 118, such that the inner stem 116 and the outer stem 118 are concentrical arranged and aligned along a central axis 113. The inner stem 116 may be a hollow or solid stem. The inner stem 116 and the outer stem 118 are selectively rotatable, relative to each other, such that one of the inner stem 116 or the outer stem 118 is rotatable, while the other one of the inner stem 116 or the outer stem 118 is fixed. A first end 117 of the pedestal 111 is attachable to the shutter apparatus 100 and a second end 119 of the pedestal 111 is attachable to a substrate carrier 206. The substrate carrier 206 includes a rotatable portion 217 and a non-rotatable portion 219. The rotatable portion 217 is the portion of the substrate carrier 206 that is capable of rotating or pivoting around the central axis 113. Conversely, the non-rotatable portion 219 is the portion of the substrate carrier 206 that remains fixed or stationary, relative to the rotatable portion 217. Depending on the configuration of the shutter apparatus 100, either the inner stem 116 of the outer stem 118 can be selectively rotatably by coupling to the rotatable portion 217 of the substrate carrier 206. This selective rotation consequently rotates either the platen 102 or the shutter 106 accordingly, as described below.

As shown in FIG. 2A, in one example, the outer stem 118 is coupled to the platen 102 at the first end 117 of the pedestal 111 and coupled to the rotatable portion 217 of the substrate carrier 206 at the second end 119 of the pedestal 111. This configuration establishes a connection between the platen 102 and the rotatable portion 217 of the substrate carrier 206, facilitated by the outer stem 118. Consequently, the platen 102, the outer stem 118 and the rotatable portion 217 are all co-rotatable in a rotation direction 105, enabling synchronized movement during operation of the substrate carrier 206. Similarly, the inner stem 116 is coupled to the shutter 106 at the first end 117 of the pedestal 111 and coupled to the non-rotatable portion 219 of the substrate carrier 206 at the second end 119 of the pedestal 111. This arrangement establishes a connection between the shutter 106 and the non-rotatable portion 219 of the substrate carrier 206, facilitated by the inner stem 11. Consequently, the shutter 106, the inner stem 116, and the non-rotatable portion 219 remain rotationally fixed.

As shown in FIG. 2B, in other examples, the outer stem 118 is coupled to the platen 102 at the first end 117 of the pedestal 111 and coupled to the non-rotatable portion 219 of the substrate carrier 206 at the second end 119 of the pedestal 111. This configuration establishes a connection between the platen 102 and the non-rotatable portion 219 of the substrate carrier 206, via the outer stem 118. Consequently, the platen 102, the outer stem 118, and the non-rotatable portion 219 remain rotationally fixed during operation of the substrate carrier 206. Similarly, the inner stem 116 is coupled to the shutter 106 at the first end 117 of the pedestal 111 and coupled to the rotatable portion 217 of the substrate carrier 206 at the second end 119 of the pedestal 111. This arrangement establishes a connection between the shutter 106 and the rotatable portion 217 of the substrate carrier 206, via the inner stem 116. Consequently, the shutter 106, the inner stem 116, and the rotatable portion 217 are co-rotatable in the rotation direction 105. Various configurations of the substrate carrier 206 and/or the pedestal 111 are possible to selectively rotate the shutter apparatus 100, including alternative arrangements of the rotatable portion 217 and the non-rotatable portion 219. For example, the rotatable portion 217 of the substrate carrier 206 may have any of various configurations such as a ring, depicted in FIG. 2A, coupled to an exterior surface of the outer stem 118, or the cylinder, depicted in FIG. 2B, coupled within the inner stem 116.

Referring to FIG. 3, the shutter apparatus 100 is depicted with the shutter 106 removed, allowing a view of the top surface of the platen 102. The platen 102 includes a central opening 107 and the plurality of substrate locations 104 that are each spaced apart from others of the plurality of substrate locations 104. The inner stem 116 of the pedestal 111 extends from the central opening 107 of the platen 102 and is coupled to the shutter 106 (not shown). The spacing of the plurality of substrate locations 104 allows for the substrate-location aperture 108 to expose only one of the plurality of substrate locations 104 at a time. In some examples, each one of the plurality of substrate locations 104 are spaced apart from others of the plurality of substrate locations an equal distance away from corresponding adjacent ones of the plurality of substrate locations 104. That is, each substrate location is the same distance from its neighboring substrate locations. The uniform spacing of the plurality of substrate locations 104 enables either the platen 102 or the shutter 106 to be rotated by the same degree to expose each one of the plurality of substrate locations 104, one at a time, through the substrate-location aperture 108. In other examples, the plurality of substrate locations 104 are non-uniformly spaced apart from others of the plurality of substrate locations 104.

The plurality of substrate locations are arranged in a circular pattern, relative to the central opening 107 of the platen 102, with the central axis 113 extending through the center of the central opening 107. In some examples, the platen 102 has a circular base 103 defining a uniform and level surface on which the plurality of substrate locations 104 are arranged. In other examples, the platen 102 may have a base with a shape other than circular, such as a rectangular base. The plurality of substrate locations 104 may be located at any distance between the central opening 107 of the platen 102 and an edge of the platen 102. For example, each one of the plurality of substrate locations 104 may be spaced an equal distance away from the central opening 107 of the platen 102. In other examples, when the platen 102 has a circular base 103, the plurality of substrate locations 104 may be spaced adjacent to a circumference of the circular base 103.

The platen 102 may include any number of substrate locations. In some examples, the plurality of substrate locations 104 includes at least two substrate locations. In other examples, the plurality of substrate locations 104 includes at least twelve substrate locations 104. In yet other examples, the plurality of substrate locations 104 includes between, and inclusive of, two and twelve substrate locations 104. In other words, although the platen 102, as shown, includes twelve substrate locations the platen 102 may include any number of substrate locations including more or less than the substrate locations shown.

A substrate 114 or a group of substrates 114 is configured to be held within a corresponding one of the plurality of substrate locations 104. In one example, a single substrate 114 is within each one of the plurality of substrate locations 104. In other examples, a group of substrates 114, such as a group of three substrates 114, is within each one of the plurality of substrate locations 104. In yet other examples, the substrate quantities within the plurality of substrate locations 104 may vary, with some locations accommodating groups of substrates while other hold single substrates.

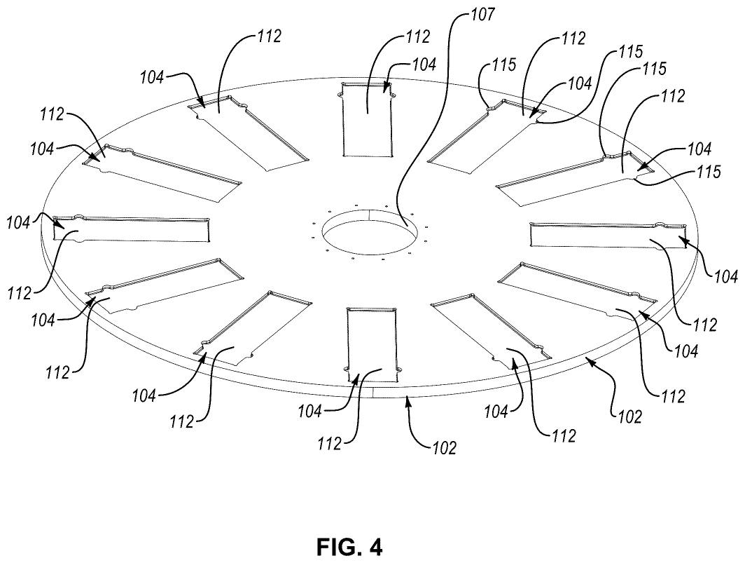

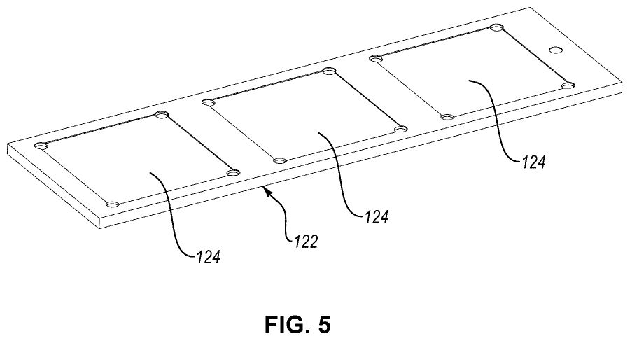

Referring to FIG. 4, the platen 102 is shown without any substrates 114 within the plurality of substrate locations 104. In some examples, each one of the plurality of substrate locations 104 defines a recess 112 within the platen 102. The recess 112 is an indentation or cavity within the top surface of the platen 102 that is configured to hold a corresponding substrate(s) 114. That is, the recess 112 is designed to accommodate the securely hold the corresponding substrate(s) 114 during the coating process. Each recess 112 ensures proper alignment and placement of the corresponding substrate(s) 114 within the platen 102. Moreover, each recess 112 may include at least one notch 115, designed to aid in substrate removal from the recess 112. Additionally, or alternatively, the plurality of substrate locations 104 may include other attachment mechanisms for securing substrates 114 to the platen 102. For example, the attachment mechanisms could include clamps, adhesives, suction, magnets, among others.

As shown in FIG. 5 is a substrate tray 122 that is configured to be held in a corresponding one of the plurality of substrate locations. The substrate tray 122 includes at least one substrate holder 124, intended to accommodate a substrate 114 (not shown). That is, in some examples, the substrate tray 122 is utilized to hold the substrate(s) 114 within the corresponding one of the plurality of substrate locations 104, as opposed to directly placing the substrate(s) 114 in the corresponding one of the plurality of substrate locations 104. Accordingly, the substrate tray 122 is sized and shaped to fit within a corresponding one of the plurality of substrate locations 104. The substrate tray 122 may vary in the number of substrate holders 124, such as more or less than the three substrate holders 124 shown.

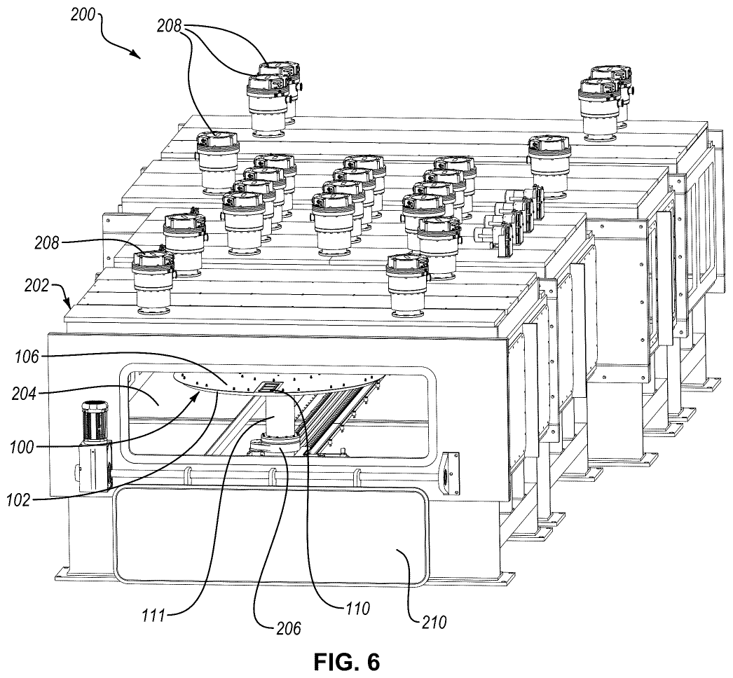

Shown FIG. 6 is one example of a vacuum coating system 200. The vacuum coating system 200 includes a vacuum chamber 202, serving as a sealable enclosure where the shutter apparatus 100 is configured to be utilized within. The vacuum chamber 202 includes a deposition chamber 204, where a vacuum is created and maintained. The deposition chamber 204 serves as the space for material deposition onto substrates. The deposition chamber 204, includes various deposition sources, such as sputtering targets. Additionally, temperature and pressure within the deposition chamber 204 is controlled to achieve desired substrate properties and deposition rates. The deposition chamber 204 is hermetically sealed by a chamber door 210, which may be equipped with specialized gaskets for an airtight enclosure. The chamber door 210 mechanism allows for controlled access to the deposition chamber 204 while preventing contamination, for optimal conditions for the coating process.

The vacuum chamber 202 also includes and at least one vacuum pump 208, which is connected to the deposition chamber 204. The at least one vacuum pump 208 maintains and regulates the desired vacuum levels of the deposition chamber 204 during the coating process. That is, the at least one vacuum pump 208 removes air and other gases from within the deposition chamber 204 to create a low-pressure environment conducive to coating processes. The at least one vacuum pump 208 can vary in size and type depending on the specific requirements of the vacuum coating system 200. The process of running a coating run and cycling from atmospheric pressure to vacuum within the deposition chamber 204, can be a time consuming process. Therefore, the shutter apparatus 100 is utilized to allow multiple substrates to be individually coated during a single coating run.

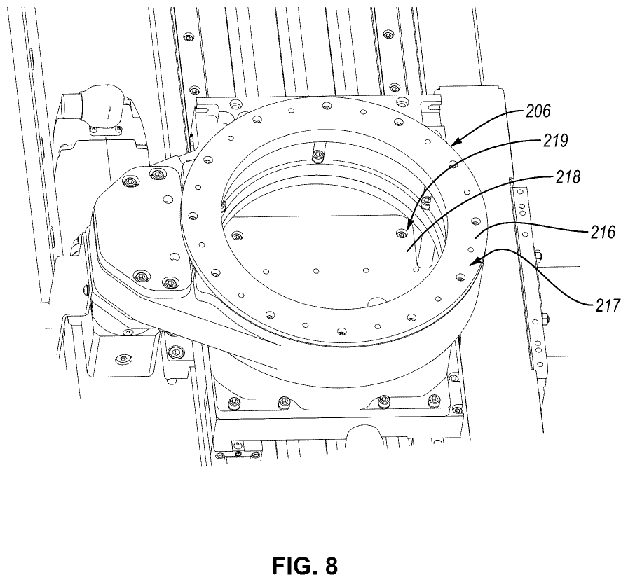

A substrate carrier 206 is within the deposition chamber 204 and serves as the platform for holding and positioning the substrates during the coating process. As shown in FIG. 8, is one example of a substrate carrier 206, including a rotatable portion 217, which is selectively rotatable relative to the deposition chamber 204, and a non-rotatable portion 219, which is non-rotatably fixed relative to the deposition chamber 204. The rotatable portion 217 is configured to be coupled to one of either the platen 102 or the shutter 106 of the shutter apparatus 100. The non-rotatable portion 219 is configured to be coupled to the other one of the platen 102 or the shutter 106. That is, when the shutter apparatus 100 is coupled to the substrate carrier 206, the platen 102 and the shutter 106 are selectively rotatable, relative to each other, to alternatingly expose a different selected one of the plurality of substrate locations 104. In some examples, the rotatable portion 217 is a rotating ring 216 and the non-rotatable portion 219 is a fixed base 218. However, other configurations of the substrate carrier 206 are possible including for example, a rotating base and a fixed ring.

Referring back to FIG. 6, the shutter apparatus 100 is coupled to the substrate carrier 206 within the deposition chamber 204 of the vacuum chamber 202. The shutter apparatus 100 includes the platen 102 and the shutter 106. The platen 102 is positioned between the substrate carrier 206 and the shutter 106, such that the shutter 106 covers all but a selectable one 110 of the plurality of substrate locations 104 of the platen, which is exposed through the substrate-location aperture 108 of the shutter 106. In some examples, the pedestal 111 is utilized to couple the substrate carrier 206 to the shutter apparatus 100. Additionally, the pedestal 111 may be used to elevate the shutter apparatus 100, raising the height of the substrates on the platen 102 to optimize their exposure to the deposition process.

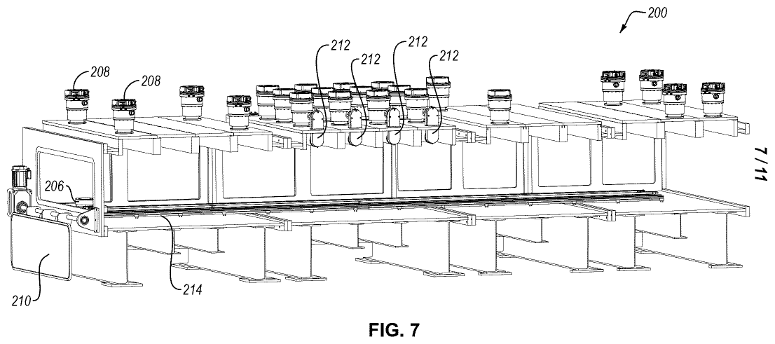

As shown in FIG. 7, is a side view of the vacuum coating system 200 with a side panel of the vacuum chamber 202 removed to view an interior of the deposition chamber 204. In some examples, the substrate carrier 206 is translationally movable along a length of the deposition chamber 204. Accordingly, the deposition chamber 204 may include a track 214, or other translational system to allow the substrate carrier 206 to traverse within the deposition chamber 204 for efficient coating processes.

The vacuum chamber 202 includes a plurality of target cylinders 212 which house the coating materials, such as metallic or compound elements, that are to be deposited onto the substrates during the coating process. The arrangement and composition of the plurality of target cylinders 212 may vary depending on needs of the coating process. In some examples, the target cylinders 212 are located along the length of the deposition chamber 204, such that as the substrate carrier 206 is translationally moved within the deposition chamber 204, the corresponding target cylinders 212 are utilized to deposited materials on the selected one 110 of the plurality of substrates 104.

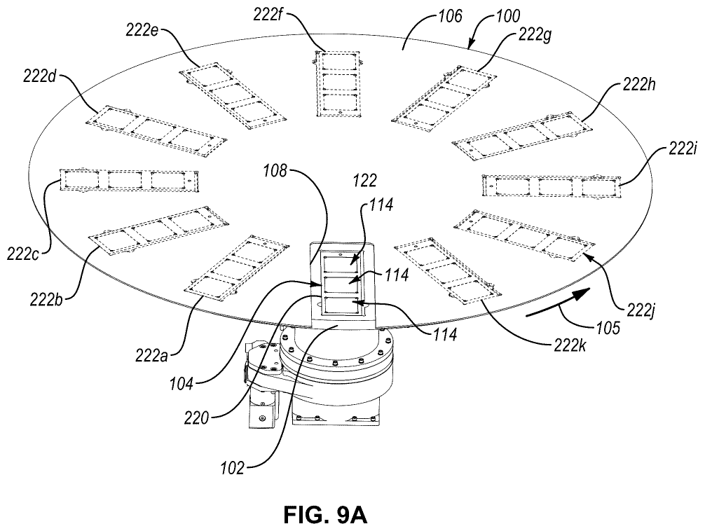

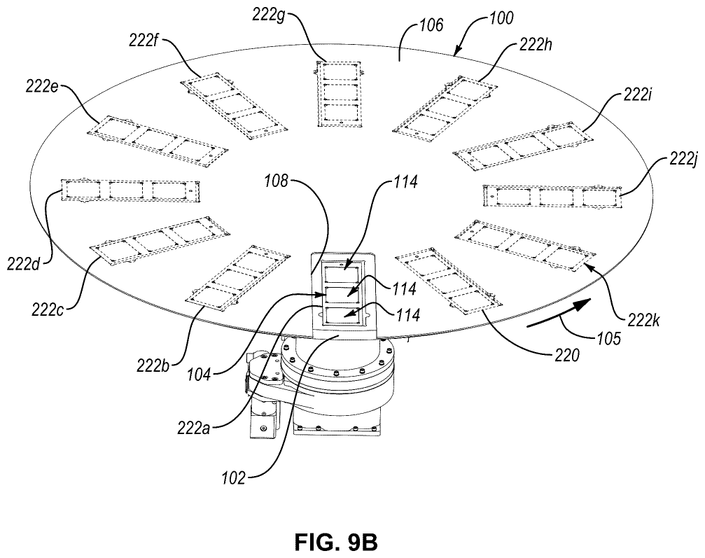

Referring to FIGS. 9A and 9B is an illustration of a method of making parts using the shutter apparatus 100. As shown in FIG. 9A, the shutter 106 is covering the platen 102 except for a selected one of the plurality of substrate locations 104, a first substrate location 220. That is, the first substrate location 220 is exposed through the substrate-location aperture 108, which is sized to expose only one of the plurality of substrate locations 104 at a time. Accordingly, the shutter 106 is covering (i.e. shielding) the remaining ones of the plurality of substrate locations 104, which are depicted with dotted lines to indicate their coverage by the shutter 106, and includes the subsequent substrate locations 222A-222K. The first substrate location 220, as well as, the subsequent substrate locations 222A-222K, have a substrate tray 122 positioned within each one of the plurality of substrate locations 104. The substrate tray 122 in the first substrate location 220 is supporting three substrates 114. When a coating process is operating inside the vacuum coating system, the material deposited on each one of the substrates within the exposed substrate location 220 is the same. That is, each of the exposed substrates 114 receives an identical deposition of material during the coating process. In other examples, the first substrate location 220 may have a single substrate.

The shutter apparatus 100 is utilized in a vacuum coating system, such as the vacuum coating system 200. Accordingly, the shutter apparatus 100 is within the deposition chamber 204 of the vacuum chamber 202 and coupled to the substrate carrier 206 and a vacuum cycle is initiated by the vacuum coating system. A vacuum cycle refers to the process of creating and maintaining a vacuum within a vacuum chamber and requires cycling from atmospheric pressure to vacuum and back to atmospheric pressure when the vacuum cycle is complete. Once the vacuum coating system reaches the desired vacuum level, a first coating process is performed to deposit material on the substrates 114 within the first substrate location 220. The first coating process may involve various techniques such as sputtering, evaporation, chemical vapor deposition, physical vapor deposition, atomic layer deposition, or electroplating to coat the substrates 114 with the depositing material. As the subsequent substrate locations 222A-222K are covered by the shutter 106, the depositing material will not be deposited within the subsequent substrate locations 222A-222K during the first coating process.

After the first coating process is completed for the first substrate location 220, and while the vacuum cycle is still active, either the platen 102 or the shutter 106 is rotated, in the rotational direction 105, to alternatingly expose a subsequent one of the plurality of substrate locations 104. In this example, the operation of the shutter apparatus 100 is described with the platen 102 rotating relative to the shutter 106, which is fixed. Accordingly, as shown in FIG. 9B, the platen 102 is rotated, via the substrate carrier 206, to alternatingly expose a subsequent one of the plurality of substrate locations 104, while the shutter remains stationary. That is, after rotating the platen 102 a certain degree, the first substrate location 220 is covered by the shutter 106, and the subsequent substrate location 222A is exposed through the substrate-location aperture 108. Accordingly, the shutter 106 is covering the remaining subsequent substrate locations, including the subsequent substrate locations 222B-222K and the first substrate location 220. During the same vacuum cycle, a second coating process is performed to deposit material on the substrates 114 within the subsequent substrate location 222A. In some examples, the depositing materials, as well as other process parameters, may be the same during the first coating process and the second coating process. In other examples, the depositing materials, or other process parameters, may be different during the first coating process and the second coating process.

After the second coating process is completed, the platen 102 can be rotated to expose the next subsequent substrate location and a third coating process can be performed during the same vacuum cycle. This process of alternatingly exposing a next one of the plurality of substrate locations 104 can be continued until the substrates 114 in each one of the plurality of substate locations 104 have had material deposited during an individual coating process. That is, during a single vacuum cycle, multiple individual coating process are performed, with the number of coating processes corresponding to the number of substrate locations 104. Traditional vacuum coating systems, without a shutter apparatus 100, require that a separate vacuum cycle is utilized for each substrate, such that each substrate would require a corresponding coating process within a separate vacuum cycle. Accordingly, the total time required to complete the coating process of the substrates in each one of the plurality of substrate locations 104, as compared to vacuum coating systems without a shutter apparatus 100, is reduced by the number of substrates or groups of substrates within the shutter apparatus 100. For example, the shutter apparatus 100 as shown can be used to perform twelve coating process within one vacuum cycle, as compared to, the twelve vacuum cycles that would be required to coat each substrate during a coating process in an individual vacuum cycle. Accordingly, the multiple substrate locations of the platen 102 and the shutter 106 facilitates efficient individual coating processes of each one of the plurality of substrate locations 104.

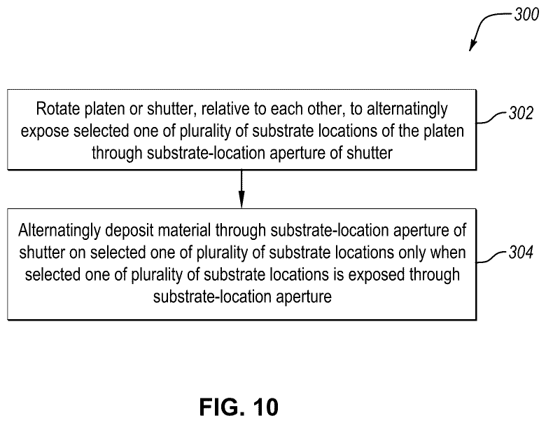

Referring to FIG. 10, according to some examples, a method 300 of making parts within a vacuum coating system 200 is shown. The parts produced by the method 300 may be a test part (e.g., test coupon), manufactured for the purpose of testing or experimentation. Test parts may be used to evaluate the performance, durability, or characteristics of a process parameters. Alternatively, the parts produced by the method 300 may be production parts that are manufactured for commercial or industrial purposes, and intended for use in a final product or application for which it is designed.

The method 300 includes the step of (block 302) rotating a platen 102 or a shutter 106, relative to each other, to alternatingly expose a selected one of a plurality of substrate locations 104 of the platen 102 through a substrate-location aperture 108 of the shutter 106. Moreover, the platen 102 is coupled to one or a rotatable portion 217 or a non-rotatable portion 219 of a substrate carrier 206 and the shutter 106 is coupled to the other one of the rotatable portion 217 or the non-rotatable portion 219 of the substrate carrier 206. The step of rotating the platen 102 or the shutter 106, relative to each other comprises rotating the rotatable portion 217 of the substrate carrier 206, relative to the non-rotatable portion 219 of the substrate carrier 206. In some examples, the platen 102 is rotatable, in a rotational direction 105, relative to the shutter 106, which is rotationally fixed. That is, the platen 102 is coupled to the rotatable portion 217 of the substrate carrier 206 and the shutter 106 is coupled to the non-rotatable portion 219. Conversely, in other examples, the shutter 106 is rotatable, in the rotational direction 105, relative to the platen 102, which is rotationally fixed. That is, the shutter 106 is coupled to the rotatable portion 217 of the substrate carrier 206 and the platen 102 is coupled to the non-rotatable portion 219.

The method also includes the step of (block 304) alternatingly depositing material through the substrate-location aperture 108 of the shutter 106 on the selected one of the plurality of substrate locations 104 only when the selected one of the plurality of substrate locations 104 is exposed through the substrate-location aperture 108. Essentially, the method 300 allows for the selective deposition of material onto specific substrate locations within the vacuum coating system 200. In some examples, the material deposited on the selected one of the plurality of substrate locations 104 is different from the material deposited on at least another selected one of the plurality of substrate locations 104. That is, the material deposited on each one of the plurality of substrate locations can be different. In other examples, the material deposited on each one of the plurality of substrate locations is the same.

In the above description, certain terms may be used such as “up,” “down,” “upper,” “lower,” “horizontal,” “vertical,” “left,” “right,” “over,” “under” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.”

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The schematic flow chart diagrams included herein are generally set forth as logical flow chart diagrams. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

The present subject matter may be embodied in other specific forms without departing from its spirit or essential characteristics. The described examples are to be considered in all respects only as illustrative and not restrictive. All changes which come within the meaning and range of equivalency of the examples herein are to be embraced within their scope.

What is claimed is:

1. A shutter apparatus for use in a part-manufacturing process, the shutter apparatus comprising:
a platen comprising a plurality of substrate locations; and
a shutter defining a substrate-location aperture and covering the platen except for a selectable one of the plurality of substrate locations of the platen exposed through the substrate-location aperture;
wherein:
the substrate-location aperture is sized to expose only one of the plurality of substrate locations at a time, such that the shutter covers all but a selected one of the plurality of substrate locations; and
the shutter and the platen are selectively rotatable, relative to each other, to alternatingly expose a different selected one of the plurality of substrate locations.

2. The shutter apparatus of claim 1, wherein the platen is rotatable, in a rotational direction, relative to the shutter, which is rotationally fixed.

3. The shutter apparatus of claim 1, wherein the shutter is rotatable, in a rotational direction, relative to the platen, which is rotationally fixed.

4. The shutter apparatus of claim 1, wherein:
the platen comprises a circular base;
the plurality of substrate locations are spaced apart about and adjacent to a circumference of the circular base; and
each one of the plurality of substrate locations is located equidistant from corresponding adjacent ones of the plurality of substrate locations.

5. The shutter apparatus of claim 1, wherein:
the plurality of substrate locations are arranged in a circular pattern;
each one of the plurality of substrate locations are spaced apart from others of the plurality of substrate locations an equal distance away from corresponding adjacent ones of the plurality of substrate locations; and
each one of the plurality of substrate locations are spaced an equal distance away from a center of the circular pattern.

6. The shutter apparatus of claim 1, wherein the plurality of substrate locations comprises between, and inclusive of, two and twelve substrate locations.

7. The shutter apparatus of claim 1, wherein the plurality of substrate locations comprises at least twelve substrate locations.

8. The shutter apparatus of claim 1, wherein each one of the plurality of substrate locations defines a recess within the platen that is configured to hold a corresponding substrate.

9. The shutter apparatus of claim 1, further comprising a pedestal having an outer stem and an inner stem, within the outer stem, wherein the outer stem is coupled to the platen and the inner stem is coupled to the shutter.

10. A vacuum coating system, comprising:
a vacuum chamber comprising a deposition chamber;
a substrate carrier within the deposition chamber and comprising a rotatable portion, which is selectively rotatable relative to the deposition chamber, and a non-rotatable portion, which is non-rotatably fixed relative to the deposition chamber;
a shutter apparatus coupled to the substrate carrier, comprising:
a platen comprising a plurality of substrate locations; and
a shutter defining a substrate-location aperture and covering the platen except for a selectable one of the plurality of substrate locations of the platen exposed through the substrate-location aperture;
wherein:
the platen is positioned between the substrate carrier and the shutter;
the substrate-location aperture is sized to expose only one of the plurality of substrate locations at a time, such that the shutter covers all but a selected one of the plurality of substrate locations;
the platen is coupled to one of the rotatable portion or the non-rotatable portion of the substrate carrier and the shutter is coupled to the other one of the rotatable portion or the non- rotatable portion of the substrate carrier; and
the platen and the shutter are selectively rotatable, relative to each other, to alternatingly expose a different selected one of the plurality of substrate locations.

11. The vacuum coating system of claim 10, wherein:
the rotatable portion of the substrate carrier comprises a rotating ring and the non-rotatable portion of the substrate carrier comprises a fixed base;
the platen is coupled to the rotating ring, such that the platen and the rotating ring are co-rotatable in a rotational direction, relative to the deposition chamber; and
the shutter is coupled to the fixed base, such that the shutter is rotationally fixed.

12. The vacuum coating system of claim 10, wherein:
the rotatable portion of the substrate carrier comprises a rotating ring and the non-rotatable portion of the substrate carrier comprises a fixed base;
the shutter is coupled to the rotating ring, such that the shutter and the rotating ring are co-rotatable in a rotational direction, relative to the deposition chamber; and
the platen is coupled to the fixed base, such that the platen is rotationally fixed.

13. The vacuum coating system of claim 10, wherein the substrate carrier is translationally movable along the deposition chamber.

14. The vacuum coating system of claim 10, further comprising a plurality of substrates, wherein each one of the plurality of substrates is configured to be positioned within a corresponding one of the plurality of substrate locations of the platen.

15. The vacuum coating system of claim 14, further comprising a plurality of substrate trays, wherein each one of the plurality of substrate trays is configured to support at least one of the plurality of substrates and wherein each one of the plurality of substrate trays is configured to be positioned within a corresponding one of the plurality of substrate locations of the platen.

16. The vacuum coating system of claim 14, wherein each one of the plurality of substrates is a test coupon.

17. The vacuum coating system of claim 14, wherein each one of the plurality of substrates is a production part.

18. A method of making parts within a vacuum coating system, the method comprising:
rotating a platen or a shutter, relative to each other, to alternatingly expose a selected one of a plurality of substrate locations of the platen through a substrate-location aperture of the shutter; and
alternatingly depositing material through the substrate-location aperture of the shutter on the selected one of the plurality of substrate locations only when the selected one of the plurality of substrate locations is exposed through the substrate-location aperture.

19. The method of claim 18, wherein:
the platen is coupled to one of a rotatable portion or a non-rotatable portion of a substrate carrier and the shutter is coupled to the other one of the rotatable portion or the non-rotatable portion of the substrate carrier; and
the step of rotating the platen or the shutter, relative to each other comprises rotating the rotatable portion of the substrate carrier, relative to the non-rotatable portion of the substrate carrier.

20. The method of claim 18, wherein the step of alternatively depositing material through the substrate-location aperture of the shutter on the selected one of the plurality of substrate locations comprises depositing material on at least another selected one of the plurality of substrate locations that is different from the material deposited on the selected one of the plurality of substrate locations.
